(19) United States
(12) Patent Application Publication
(10) Pub. No.: US 2002/0006675 A1
(43) Pub. Date: Jan. 17, 2002

(54) Semiconductor manufacturing apparatus and method of manufacturing semiconductor devices

(76) Inventor: Toshiyuki Shigaraki, Tochigi (JP)

Correspondence Address: FITZPATRICK CELLA HARPER & SCINTO, 30 ROCKEFELLER PLAZA, NEW YORK, NY, 10112, US

(21) Appl. No.: 09/851,158

(22) Filed: May 9, 2001

(30) Foreign Application Priority Data
May 17, 2000 (JP) 2000-144281

(51) Int. Cl. H01L 21/00

(52) U.S. Cl. 438/4; 438/909; 438/905

(57) ABSTRACT

A semiconductor manufacturing apparatus for executing an exposure process upon filling a chamber, an illuminating optics unit and a projection optics unit with an inert gas is provided with a supply unit that supplies clean, dry air for raising the concentration of oxygen in a maintenance area, and with a sensor for sensing oxygen concentration or ozone concentration in the maintenance area. When maintenance is carried out, the supply unit is actuated to raise the oxygen concentration in the maintenance area, thereby assuring the safety of workers. A maintenance cover is provided with a door switch for sensing that the cover has been opened. Actuation of the supply unit is started in accordance with the state sensed by the door switch. Alternatively, the supply unit is actuated on the basis of an input ordering the start of a maintenance operation. If the environment in the maintenance area has not reached a level that safe for the human body, a warning lamp is lit to so alert workers and the maintenance cover is kept locked.

### FIELD OF THE INVENTION

This invention relates to a semiconductor manufacturing apparatus, such as a semiconductor exposure apparatus, and to a method of manufacturing semiconductor devices, in which maintenance can be performed safely and rapidly.

### BACKGROUND OF THE INVENTION

It is required that a semiconductor exposure apparatus be capable of providing ever greater micromachining precision and have the ability to create fine patterns to cope with the fabrication of increasingly miniscule semiconductor elements. Light sources which emit light of shorter and shorter wavelengths are being used as the exposure light source. For example, ultraviolet and extreme ultraviolet light sources such as an ArF excimer laser (having a wavelength of 192 nm) and a KrF excimer laser (having a wavelength of 248 nm) are being used. Among the wavelengths of the light emitted from these light sources, the wavelength (192 nm) of the ArF excimer laser light substantially coincides with the absorption wavelengths (193.28 nm, 193.70 nm) of oxygen. The energy of the exposing light also is extremely large, i.e., greater than 2 kJ. If irradiation is performed at the absorption wavelength of oxygen and with high energy, oxygen changes to ozone. It has been confirmed that ozone in high concentrations is harmful to the human body. In addition, owing to contact between the exposing light and impurities in the air, oxides attach themselves to the surfaces of lenses in the illuminating optical system and exposure projecting optical system. This causes a decline in the transmittance of light. In order to prevent this phenomenon, the interior of the illuminating optical system or projecting optical system in the semiconductor manufacturing apparatus is filled with an inert gas such as nitrogen or helium, or these optical systems are filled with clean, dry air and the clean, dry air is made to react positively with the exposing light to produce ozone. The result is the elimination of organic matter.

When maintenance is performed in a semiconductor manufacturing apparatus of this type, there is an area that is predicted to be filled with an inert gas or an area in which the generation of toxic gas such as ozone that is harmful to the human body is predicted. The maintenance work is performed after opening a maintenance cover and waiting for the maintenance area to be supplied with a satisfactory amount of oxygen. It is necessary, therefore, to warn the maintenance individual of the hazards as by displaying a label indicating a hazardous condition, i.e., that there may not be sufficient supply of oxygen, or by describing this situation in a maintenance manual.

In the prior art described above, however, the determination as to whether an inert gas remains inside the apparatus during maintenance is unreliable and the maintenance work cannot be carried out safely. Further, safety cannot be guaranteed when safety measures are disregarded or when the service individual overlooks the instructions on a label or the like. Furthermore, in order to perform maintenance after the oxygen concentration in the maintenance area has risen satisfactorily to assure a safe condition, it is necessary to wait for the oxygen concentration to rise sufficiently. This means that maintenance takes time.

### SUMMARY OF THE INVENTION

Accordingly, an object of the present invention is to provide a semiconductor manufacturing apparatus and a semiconductor device manufacturing method in which worker safety is assured and maintenance can be performed rapidly when the semiconductor manufacturing apparatus undergoes maintenance.

According to the present invention, the foregoing object is attained by providing a semiconductor manufacturing apparatus comprising control means for externally setting a low oxygen concentration in an internal space, and means for blowing a gas in order to raise the oxygen concentration of an area that is at least part of the internal space.

It is preferred that the gas for raising the oxygen concentration in the semiconductor manufacturing apparatus of the invention be clean, dry air.

It is preferred that the area that is part of the internal space be a maintenance area for performing maintenance on the semiconductor manufacturing apparatus.

It is preferred that the semiconductor manufacturing apparatus further include a sensor for sensing the oxygen concentration inside the internal space, that the sensor sense the oxygen concentration in the maintenance area, and that the semiconductor manufacturing apparatus further include a monitor for displaying results output by the sensor.

It is preferred that the semiconductor manufacturing apparatus further include sensing means for outputting a signal when the maintenance area is accessed, and that the sensing means sense an operation for opening a maintenance cover when the maintenance area is accessed and output a signal indicative of this operation.

It is preferred that the means for blowing the gas in order to raise the oxygen concentration be made to operate based upon the signal output when the maintenance area is accessed.

It is preferred that the maintenance cover of the maintenance area be locked if the oxygen concentration in the maintenance area is below a predetermined value, as a result of which the maintenance cover cannot be opened.

It is preferred that the semiconductor manufacturing apparatus of the invention be so adapted that the means for blowing the air can be controlled from a console for operating the semiconductor manufacturing apparatus.

It is preferred that the semiconductor manufacturing apparatus of the invention be so adapted that the oxygen concentration in the maintenance area can be controlled based upon the setting of a maintenance mode at the console.

It is preferred that the semiconductor manufacturing apparatus further include a second sensor for sensing the concentration of a toxic gas inside the internal space, wherein if the concentration of the toxic gas is greater than a predetermined value, the maintenance cover of the maintenance area is locked so that the maintenance cover cannot be opened.

It is preferred that the semiconductor manufacturing apparatus of the invention further include a display, a network interface and a computer for running network access software, wherein maintenance information concerning the semiconductor manufacturing apparatus is capable of being communicated by data communication via a computer network. Further, it is preferred that the network access software provide the display with a user interface for accessing a maintenance database provided by a vendor or user of the semiconductor manufacturing apparatus, so that information can be obtained from the database via the Internet or a leased-line network connected to the computer network.

A method of manufacturing semiconductor devices according to the present invention comprises steps of placing a group of manufacturing equipment for various processes, inclusive of the above-described semiconductor manufacturing apparatus, in a plant for manufacturing semiconductor devices, and manufacturing a semiconductor device by a plurality of processes using this group of manufacturing equipment.

It is preferred that the method of manufacturing semiconductor devices according to the present invention further include the steps of interconnecting the group of manufacturing equipment by a local-area network, and communicating, by data communication, information relating to at least one item of manufacturing equipment in the group thereof between the local-area network and the Internet or a lease-line network serving as an external network outside the plant.

In a preferred embodiment of the method of manufacturing semiconductor devices according to the present invention, maintenance information for the manufacturing equipment is obtained by accessing, by data communication via the external network, a database provided by a manufacturer of semiconductor devices or by a supplier of the semiconductor manufacturing apparatus, or production management is performed by data communication with a semiconductor manufacturing plant other than the first-mentioned plant via the external network.

In accordance with the semiconductor manufacturing apparatus of the present invention, a gas for raising oxygen concentration is blown into a chamber which contains the exposure optics when maintenance is applied to an area in which oxygen concentration is set to a low value or to an area in which a toxic gas such as ozone, which is harmful to the human body, is produced. As a result, the environment in the area to undergo maintenance can be brought to a safe level rapidly. Further, the condition of the environment such as the oxygen concentration or ozone concentration is sensed and whether the sensor output indicates that a level safe for the human body has been attained is reported. As a result, maintenance can be performed reliably after the condition of the environment has reached the safe level and the safety of workers in the maintenance area can be assured. This makes it possible to carry out maintenance safely at all times. In addition, maintenance can be performed in a shorter period of time and the efficiency of maintenance can be improved.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

The accompanying drawings, which are incorporated in and constitute a part of the specification, illustrate embodiments of the invention and, together with the description, serve to explain the principles of the invention.

FIG. 1A is a schematic view illustrating the structure of a semiconductor manufacturing apparatus according to an embodiment of the present invention;

FIG. 1B is a schematic view showing the vicinity of a maintenance cover in the semiconductor manufacturing apparatus according to this embodiment;

FIG. 2 is a block diagram illustrating an arrangement for assuring safety at the time of maintenance in a semiconductor apparatus according to this embodiment;

FIG. 3 is a flowchart illustrating an example of a procedure followed when maintenance is performed on the semiconductor manufacturing apparatus of the present invention;

FIG. 4 is a flowchart illustrating another example of a procedure followed when maintenance is performed on the semiconductor manufacturing apparatus of the present invention;

FIG. 5 is diagram showing the overall configuration of a semiconductor device production system;

FIG. 6 is diagram showing the overall configuration of another form of semiconductor device production system;

FIG. 7 shows an example of a user interface on an input screen of a troubleshooting database;

FIG. 8 is a flowchart illustrating a process for manufacturing semiconductor devices; and

FIG. 9 is a flowchart illustrating a wafer process.

### DESCRIPTION OF THE PREFERRED EMBODIMENTS

Preferred embodiments of the present invention will now be described in detail in accordance with the accompanying drawings.

<First Embodiment>

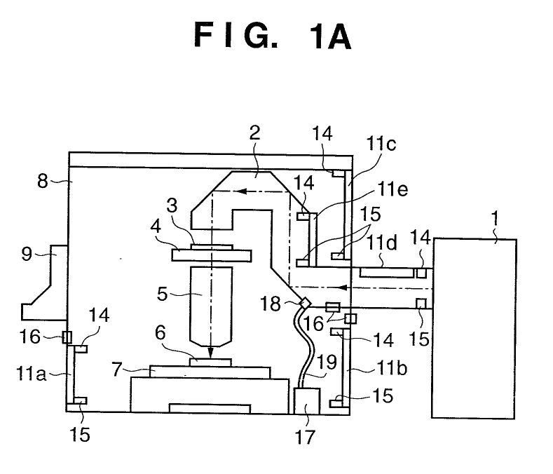

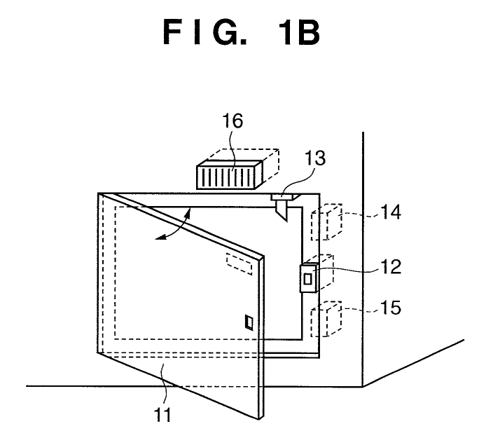

FIG. 1A is a schematic view illustrating the structure of a semiconductor manufacturing apparatus according to the present invention, and FIG. 1B is a schematic view showing the vicinity of a maintenance cover in the semiconductor manufacturing apparatus according to the invention.

The semiconductor manufacturing apparatus shown in FIGS. 1A and 1B includes a light source 1 for emitting light of short wavelength, and an illuminating optics unit 2 for leading the light emitted from the light source 1 to a reticle 3 on which an exposure pattern has been formed. The reticle 3 is placed on a reticle stage 4. The latter moves the reticle 3, positions it precisely and fixes it. When exposure is carried out, the reticle stage 4 scans the reticle 3. The apparatus further includes an exposure projecting optics unit 5. A wafer 6 to undergo exposure is placed on a wafer stage 7. The latter moves the wafer 6 to an exposure position or scans the wafer 6 in sync with the reticle 3.

A chamber 8 is for performing a precise temperature adjustment of the overall apparatus. A console 9 for operating the semiconductor manufacturing apparatus is disposed outside the chamber 8. The console 9 has a display unit (monitor) which displays wafer information for processing a wafer by the semiconductor manufacturing apparatus, recipe information and the operating status of the apparatus, and an input unit for inputting data and information necessary for the apparatus proper. The input unit can be used to enter a command to change over to various modes, such as ordinary processing mode and a maintenance mode, so that the semiconductor manufacturing apparatus can be set to each of these modes. When an ordinary processing operation or maintenance work is performed, various data is checked on the display unit of the console 9 and data and information necessary for the ordinary processing operation or maintenance work can be entered using the input unit.

Maintenance covers 11 (11a, 11, . . . ) are disposed at a plurality of locations and are capable of being opened and closed so that access can be gained to various maintenance areas in order to maintain the various components within the chamber 8 as well as the interior of the illuminating optics unit 2, etc. The maintenance covers 11a to 11c are provided on the chamber 8, and the maintenance covers 11d, 11e are provided on the illuminating optics unit 2. As shown in FIG. 1B, each maintenance cover 11 (11ato 11e) is provided with a switch 12 which, in response to the opening and closing of the maintenance cover 11, is turned on and off to output a signal indicative of the open/closed state of the maintenance cover 11, and with a lock plunger 13 for being locked in such a manner that the maintenance cover 11 cannot be opened.

Also provided in the vicinity of each maintenance cover 11 are an oxygen concentration sensor 14 for measuring the oxygen concentration inside the chamber 8 and inside the illuminating optics unit 2, and an ozone sensor 15 for sensing a toxic gas such as ozone inside the chamber 8 and inside the illuminating optics unit 2. A fan 16 for exhausting gas from inside the chamber 8 and illuminating optics unit 2 and for introducing the outside air is disposed in close proximity to the position at which the maintenance cover is attached. As mentioned above, it has been confirmed that the human body is adversely affected by an increase in ozone concentration owing to a reaction between oxygen and the exposing light caused by irradiation with high-energy exposing light at the absorption wavelength of oxygen. Accordingly, the ozone sensor 15 is provided to sense ozone in the maintenance area.

Further, a supply unit 17 is provided for supplying the interior of the chamber 8 with clean, dry air. The air supply unit 17 is adapted so as to supply clean, dry air from a supply valve 18 via a supply passageway 19. The supply unit 17 is driven in response to the switch 12 being turned on by the opening of the maintenance cover 11 or by the setting of the maintenance mode at the console 9. Maintenance work can be performed safely by supplying the clean, dry air from the supply valve 18 to raise the oxygen concentration in the maintenance area.

The semiconductor manufacturing apparatus constructed as set forth above is operated by a worker at the console 9. By setting the processing mode at the time of ordinary exposure processing, this processing starts in accordance with an exposure sequence. At this time an inert gas such as nitrogen or helium is supplied to the interior of the chamber 8 and illuminating optics unit 2 by an inert gas supply unit, which is not shown. As described earlier, owing to contact between impurities in the air and the exposing light emitted from a light source such as an ArF or KrF excimer laser used as the light source 1 for semiconductor exposure, oxides attach themselves to the surfaces of lenses in the illuminating optics unit 2 and exposure projecting optics unit 5, thereby causing a decline in the transmittance of light. In order to prevent this, the inert gas supply unit fills the interiors of the illuminating optics unit 2 and exposure projecting optics unit 5 inside the chamber 8 with an inert gas such as nitrogen or helium. Alternatively, the interiors of the illuminating optics unit 2 and exposure projecting optics unit 5 may be filled with clean, dry air and the clean, dry air may be made to react positively with the exposing light to produce ozone. The result is the elimination of organic matter.

If the chamber 8 or the interior of the illuminating optics unit 2, etc., is filled with inert gas, short-wavelength exposing light is emitted from the light source 1 and the exposing light is shaped via the illuminating optics unit 2 so that the image of the exposure pattern on the reticle 3 is formed on the wafer 6 via the exposure projecting optics unit 5. At this time the reticle stage 4 and wafer stage 7 are positioned extremely precisely to attain an overlap precision of less than 1 μm. The exposure shots on the wafer 6 are repeatedly subjected to full exposure to transfer the exposure pattern. In a scanning stepper, in addition to the stepping operation, the reticle stage 4 and wafer stage 7 are subjected to a scanning operation synchronously on a per-shot basis.

If ozone having a concentration in excess of a fixed value is sensed by the ozone sensor 15 in a case where exposure processing is being performed by the usual exposure sequence described above, the exposure sequence is terminated and so is the emission of light from the light source 1.

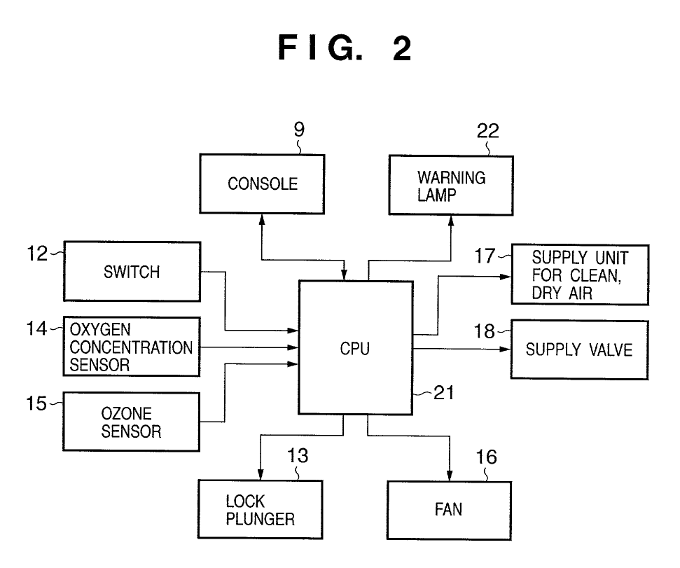

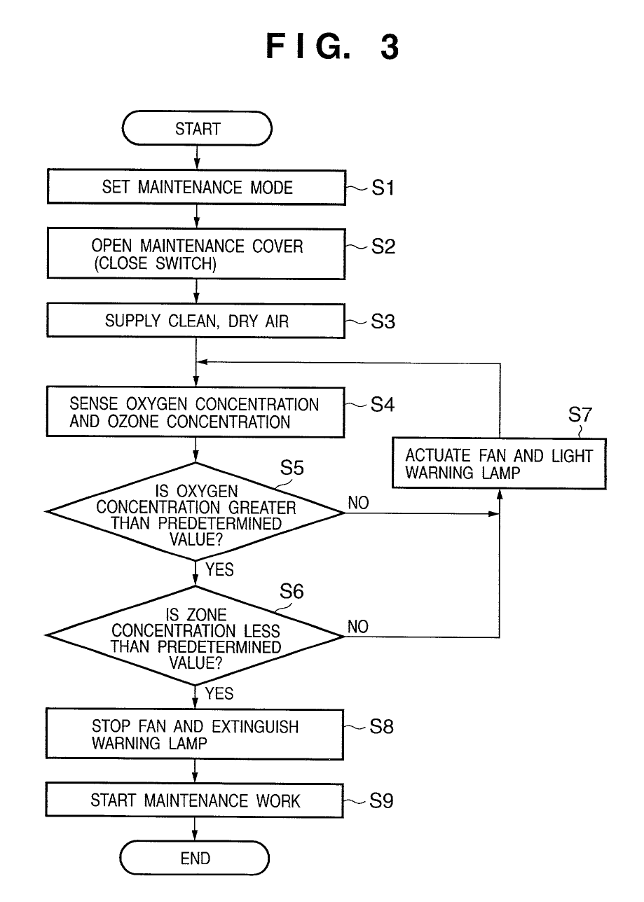

Reference will now be had to the block diagram of FIG. 2 and flowchart of FIG. 3 to describe the procedure followed when performing maintenance on the apparatus.

FIG. 2 is a block diagram useful in describing an arrangement for assuring safety when maintenance is performed in this embodiment. In FIG. 2, a CPU 21 executes a variety of control operations for controlling the above-described semiconductor manufacturing apparatus. Signals from the aforementioned switch 12, lock plunger 13, oxygen concentration sensor 14 and ozone sensor 15 are input to the CPU 21, which proceeds to drive and control the fan 16, the supply unit 17 for supplying the clean, dry air, the supply valve 18 and a warning lamp 22 in order that safety at the time of maintenance will be assured. This is one function of the CPU 21. The warning lamp 22 is for giving notification of the fact that the atmosphere in the maintenance area is hazardous. It should be noted that the switch 12, oxygen concentration sensor 14, ozone sensor 15, lock plunger 13, fan 16 and warning lamp 22 are provided for each maintenance area (maintenance area).

A worker first changes over the mode to set the maintenance mode using the console 9 (step S1). When the transition is made to the maintenance mode, the lock plunger 13 is released so that the maintenance cover 11 can be opened. An arrangement may be adopted in which by specifying a desired maintenance cover by the console 9, the lock plunger 13 that corresponds to the specified maintenance cover is released. Next, the worker goes to the area of the apparatus where maintenance is to be performed and, as shown in FIG. 1B, opens the maintenance cover 11 so that the maintenance area can be accessed and subjects the apparatus to maintenance (step S2). The switch 12 is closed (turned on) by opening the maintenance cover 11, the supply unit 17 for clean, dry air is driven by a signal from the switch 12, and clean, dry air is blown into the maintenance area from the supply valve 18 via the supply passageway 19 (step S3). By virtue of this operation, the oxygen concentration in the maintenance area rises to assure a satisfactory oxygen concentration in the maintenance area, thereby allowing the maintenance work to be conducted safely.

Even though the switch 12 is closed following the opening of the maintenance cover 11, a hazardous condition may continue for a period of time. During the time that the oxygen concentration sensor 14 and ozone sensor 15 sense values that do not indicate safety with regard to the human body (steps S4 to S6), the fan 16 is caused to operate and the warning lamp 22 provided for the corresponding maintenance cover is lit (step S7). Owing to the operation of the fan 16, outside air is forcibly drawn into the chamber (the maintenance area) to exhaust the gas from the maintenance area. By thus mixing outside air with the environment inside the maintenance area, safety against hazardous oxygen or ozone concentration is fully assured. If the results of sensing from the oxygen concentration sensor 14 and ozone sensor 15 indicate that levels for human safety have been attained, the warning lamp 22 is extinguished and the worker is notified that the maintenance work can proceed safely (step S8). The worker starts the maintenance work in response to extinguishment of the warning lamp 22 (step S9).

Thus, clean, dry air is supplied to the maintenance area, the oxygen concentration and ozone concentration are sensed and the maintenance work is started after it has been confirmed that these concentrations have attained safe levels. As a result, worker safety in the maintenance area can be assured and work can be performed safely at all times.

FIG. 1A illustrates only the vicinity of the maintenance area for the illuminating optics unit 2 in relation to the supply valve 18 that serves as the port for supplying air from the supply unit 17 for clean, dry air. However, it goes without saying that the supply valve is provided also in the vicinity of the maintenance area within the chamber 8. One supply valve 18 may be provided for each maintenance area corresponding to a maintenance cover, or an arrangement may be adopted in which one supply valve 18 is shared by several maintenance areas.

Further, an arrangement may be adopted in which clean, dry air is supplied by operating only the supply valve 18 of the maintenance area corresponding to the maintenance cover that has been opened, or an arrangement may be adopted in which all of the supply valves 18 are operated by opening at least one maintenance cover.

In case of an apparatus in which the chamber has been filled with an inert gas, the oxygen concentration sensor 14 will suffice and the ozone sensor 15 need not be used. Conversely, with an apparatus in which ozone is produced positively, the ozone sensor 15 will suffice and the oxygen concentration sensor 14 need not be used. However, from the standpoint of providing safety with a greater degree of certainty, is it preferred that both the oxygen concentration sensor 14 and the ozone sensor 15 be provided in the manner described above.

<Second Embodiment>

According to the above-described embodiment, the environment of a maintenance area is placed in a safe condition by sensing opening of a maintenance cover, and whether the safety of the environment in the maintenance area is assured is reported to the user by a warning lamp. According to a second embodiment, if transition to a maintenance mode has been specified via the console 9, the environment of a maintenance area is shifted to a safe condition and the maintenance cover is kept in a locked state until the safety of the environment is assured.

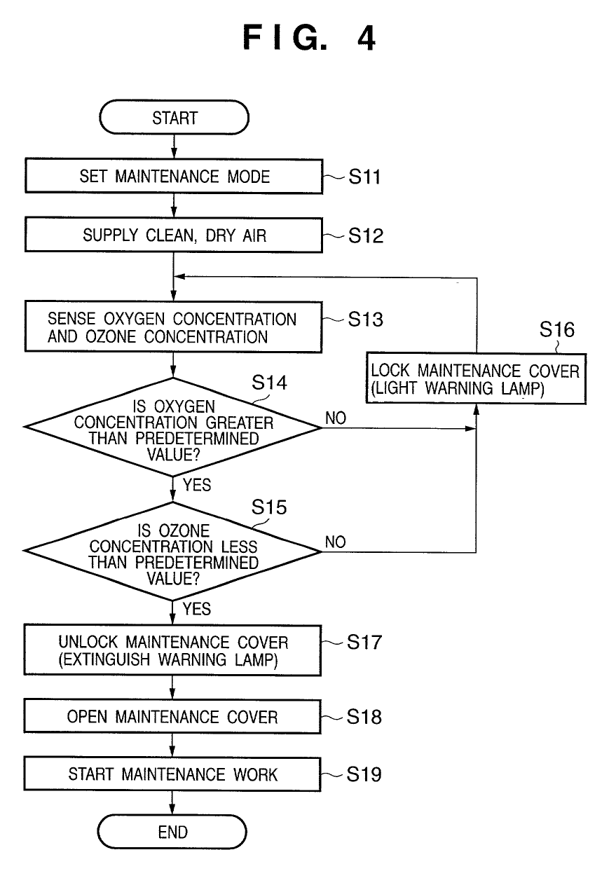

Reference will be had to FIG. 4 to describe the procedure followed when performing maintenance on the semiconductor manufacturing apparatus according to the second embodiment.

A worker changes over the mode to set the maintenance mode using the console 9 as described earlier (step S11). If the maintenance mode is set, the supply unit 17 for clean, dry air is driven in response thereto so that clean, dry air is blown into the maintenance area from the supply valve 18 via the supply passageway 19 (step S12). In this embodiment, the oxygen concentration and ozone concentration in the maintenance area are checked by the oxygen concentration sensor 14 and ozone sensor 15 (step S13) before the lock plunger 13 is unlocked to enable opening of the maintenance cover 11. If oxygen concentration and ozone concentration sensed by the oxygen concentration sensor 14 and 15 are not at safe levels with regard to the human body (steps S14, S15), the lock plunger 13 of the maintenance cover 11 is maintained in the actuated state to keep the maintenance cover 11 locked so that it cannot be opened. If the warning lamp 22 has been provided in correspondence with this maintenance cover 11, then the warning lamp 22 is lit (step S16).

The maintenance cover 11 is kept in the locked state until the values relating to oxygen concentration and ozone concentration from the oxygen concentration sensor 14 and ozone sensor 15 indicate that safe levels have been attained by the supply of clean, dry air obtained by driving the supply unit 17 or by the introduction of outside air obtained by operating the fan 16. If the results of sensing by the oxygen concentration sensor 14 and ozone sensor 15 indicate that safe levels have been attained, the maintenance cover 11 is unlocked so that it can be opened and the warning lamp 22 is lit (step S17). The worker thenceforth opens the maintenance cover 11 to start the maintenance work (steps S18, S19).

Thus, in the second embodiment, clean, dry air is supplied to the maintenance area beforehand, the oxygen and ozone concentrations are sensed, the maintenance cover is kept locked if the oxygen and ozone concentrations have not attained safe levels, and it is arranged so that the maintenance cover cannot be opened, i.e., so that the maintenance area cannot be accessed, until the oxygen and ozone concentrations attain safe levels. This better assures the safety of the worker in the maintenance area and makes it possible to perform work safely at all times.

In the example described above, clean, dry air is supplied to all maintenance areas in the chamber 8 and illuminating optics unit 2 if a transition to the maintenance mode is ordered using the console 9. The warning lamp 22 is extinguished and the lock plunger 13 is released on a per-maintenance-area basis when the environment has attained a safe level in each maintenance area. However, an arrangement may be adopted in which a maintenance area desired to be subjected to maintenance can be specified by the console 9 and the above-described supply of clean, dry air and control of the lock plunger 13 are performed with regard to the specified maintenance area.

Further, an arrangement may be adopted in which the results of sensing by the oxygen concentration sensor 14 and ozone sensor 15 corresponding to each maintenance cover 11 are displayed on a monitor of the console 9 so that the results from each sensor can be checked on the monitor. This makes it easy to ascertain the environment in each maintenance area.

Furthermore, it is possible to provide the console 9 with a warning lamp that issues a warning when the results of sensing from the oxygen concentration sensor 14 and ozone sensor 15 indicate that safe levels have not been attained. As a result, if a warning is not being issued in relation to a maintenance cover 11 of a maintenance area planned to undergo maintenance, i.e., if the results of sensing from the oxygen concentration sensor 14 and ozone sensor 15 indicate that safe levels have been obtained, a worker can access the maintenance area immediately to conduct maintenance work.

Further, it may be so arranged that if a warning is being issued in relation to a maintenance cover 11 of a maintenance area, the worker actuates the supply unit 17 for clean, dry air remotely using the console 9 to supply clean, dry air to the desired maintenance area from the supply valve 18, after which the worker can subject the area to maintenance. As a result, when the worker arrives at the maintenance area and opens the maintenance cover 11 for the purpose of performing maintenance, the oxygen and ozone concentrations in the maintenance area will already be at safe levels, thereby enabling the maintenance work to be performed promptly.

Described next will be a system for producing semiconductor devices utilizing the above-described semiconductor manufacturing apparatus. This system for producing semiconductor devices (semiconductor chips such as IC and LSI chips, liquid crystal panels, CCDs, thin-film magnetic heads and micromachines, etc.) utilizes a computer network outside the semiconductor manufacturing plant to provide troubleshooting and regular maintenance of manufacturing equipment installed at the semiconductor manufacturing plant and to furnish maintenance service such as the provision of software.

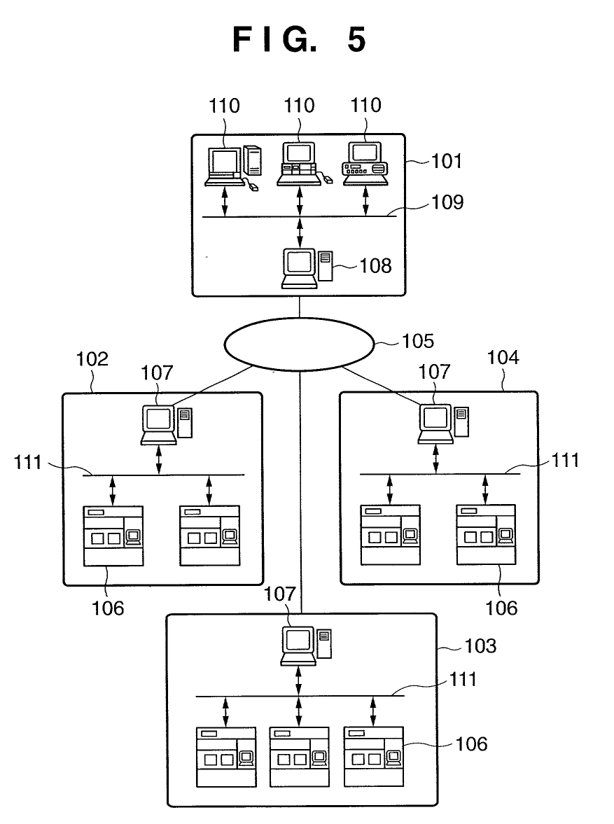

FIG. 5 is a schematic view illustrating the overall system. The system includes the business office 101 of the vendor (equipment supplier) that provides the equipment for manufacturing semiconductor devices. Semiconductor manufacturing equipment for various processes used in a semiconductor manufacturing plant is assumed to be the manufacturing equipment. Examples of the equipment are pre-treatment equipment (lithographic equipment such as exposure equipment, resist treatment equipment and etching equipment, heat treatment equipment, thin-film equipment and smoothing equipment, etc.) and post-treatment equipment (assembly equipment and inspection equipment, etc.). The business office 101 includes a host management system 108 for providing a manufacturing-equipment maintenance database, a plurality of control terminal computers 110, and a local-area network (LAN) 109 for connecting these components into an intranet. The host management system 108 has a gateway for connecting the LAN 109 to the Internet 105, which is a network external to the business office 101, and a security function for limiting access from the outside.

Numerals 102 to 104 denote manufacturing plants of semiconductor makers which are the users of the manufacturing equipment. The manufacturing plants 102 to 104 may be plants belonging to makers that differ from one another or plants belonging to the same maker (e.g., pre-treatment plants and post-treatment plants, etc.). Each of the plants 102 to 104 is provided with a plurality of pieces of manufacturing equipment 106, a local-area network (LAN) 111 which connects these pieces of equipment to construct an intranet, and a host management system 107 serving as a monitoring unit for monitoring the status of operation of each piece of manufacturing equipment 106.

The host management system 107 provided at each of the plants 102 to 104 has a gateway for connecting the LAN 111 in each plant to the Internet 105 serving as the external network of the plants. As a result, it is possible for the LAN of each plant to access the host management system 108 on the side of the vendor 101 via the Internet 105. By virtue of the security function of the host management system 108, users allowed to access the host management system 108 are limited.

More specifically, status information (e.g., the condition of manufacturing equipment that has malfunctioned), which indicates the status of operation of each piece of manufacturing equipment 106, can be reported from the plant side to the vendor side. In addition, information in response to such notification (e.g., information specifying how to troubleshoot the problem, troubleshooting software and data, etc.), as well as the latest software and maintenance information such as help information, can be acquired from the vendor side.

A communication protocol (TCP/IP), which is used generally over the Internet, can be employed for data communication between the plants 102˜104 and the vendor 101 and for data communication over the LAN 111 within each plant. Instead of utilizing the Internet as the external network of a plant, it is also possible to utilize a highly secure leased-line network (ISDN, etc.) that cannot be accessed by a third party. Further, the host management system is not limited to that provided by a vendor, for an arrangement may be adopted in which the user constructs a database, places it on an external network and allows the database to be accessed from a number of plants that belong to the user.

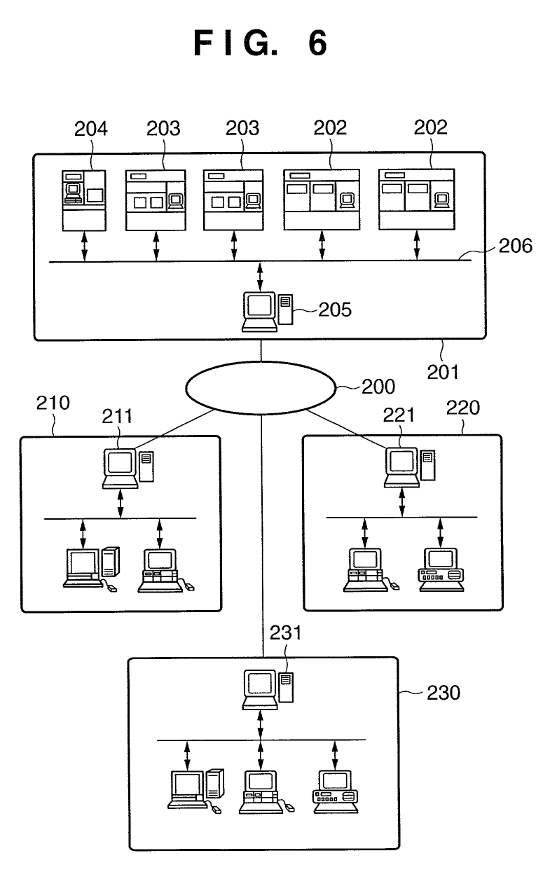

FIG. 6 is a schematic view illustrating the overall semiconductor device production system as seen from an angle different from that depicted in FIG. 5. In the above-described example, a plurality of user plants each having manufacturing equipment are connected by an external network to the management system of the vendor that provided the manufacturing equipment, and information concerning the production management of each plant and information concerning at least one piece of manufacturing equipment is communicated by data communication via the external network. In the example of FIG. 6, on the other hand, a plant having manufacturing equipment provided by a plurality of vendors is connected by an outside network to management systems of respective ones of the vendors of these plurality of pieces of manufacturing equipment, and maintenance information for each piece of manufacturing equipment is communicated by data communication.

This system includes a manufacturing plant 201 of the user of manufacturing equipment (the maker of semiconductor devices). The manufacturing line of this plant includes manufacturing equipment for implementing a variety of processes. Examples of such equipment are exposure equipment 202, resist treatment equipment 203 and thin-film treatment equipment 204. Though only one manufacturing plant 201 is shown in FIG. 6, in actuality a plurality of these plants are networked in the same manner. The pieces of equipment in the plant are interconnected by a LAN 206 to construct an intranet and the operation of the manufacturing line is managed by a host management system 205.

The business offices of vendors (equipment suppliers) such as an exposure equipment maker 210, resist treatment equipment maker 220 and thin-film treatment equipment maker 230 have host management systems 211, 221, 231, respectively, for remote maintenance of the equipment they have supplied. These have maintenance databases and gateways to the outside network, as described earlier. The host management system 205 for managing each piece of equipment in the manufacturing plant of the user is connected to the management systems 211, 221, 231 of the vendors of these pieces of equipment by the Internet or leased-line network serving as an external network 200. If any of the series of equipment in the manufacturing line malfunctions, the line ceases operating. However, this can be dealt with rapidly by receiving remote maintenance from the vendor of the faulty equipment via the Internet 200, thereby making it possible to minimize line downtime.

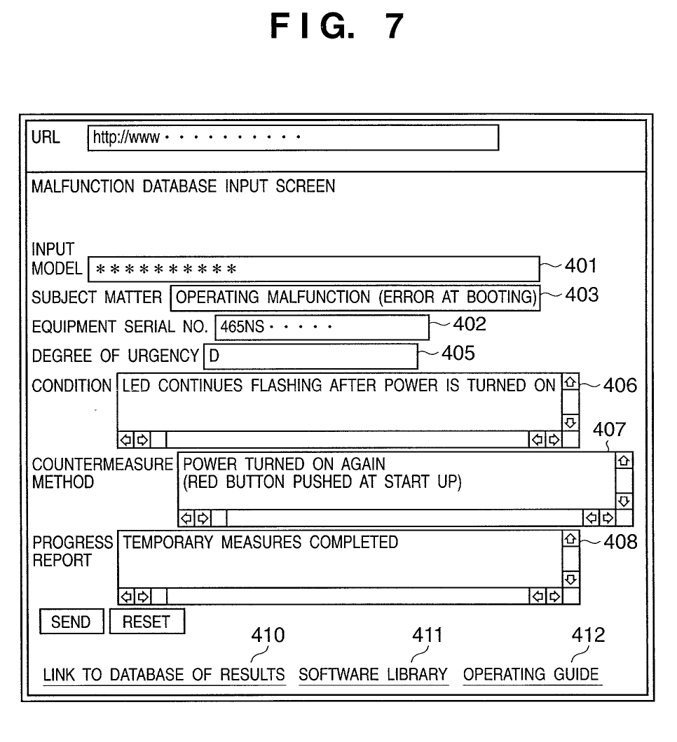

Each piece of manufacturing equipment installed in the semiconductor manufacturing plant has a display, a network interface and a computer for executing network-access software and equipment operating software stored in a storage device. The storage device can be an internal memory or hard disk or a network file server. The software for network access includes a special-purpose or general-purpose Web browser and presents a user interface, which has a screen of the kind shown by way of example in FIG. 7, on the display. The operator managing the manufacturing equipment at each plant enters information at the input items on the screen while observing the screen. The information includes model 401 of the manufacturing equipment, its serial number 402, subject matter 403 of the problem, its date of occurrence 404, degree of urgency 405, the particular condition 406, countermeasure method 407 and progress report 408. The entered information is transmitted to the maintenance database via the Internet. The appropriate maintenance information is sent back from the maintenance database and is presented on the display screen.

The user interface provided by the Web browser implements hyperlink functions 410 to 412 as illustrated and enables the operator to access more detailed information for each item, to extract the latest version of software, which is used for the manufacturing equipment, from a software library provided by the vender, and to acquire an operating guide (help information) for reference by the plant operator. Here the maintenance information provided by the maintenance database also includes the above-described information relating to the present invention, and the software library also provides the latest software for implementing the present invention.

A process for manufacturing a semiconductor device utilizing the production system set forth above will now be described.

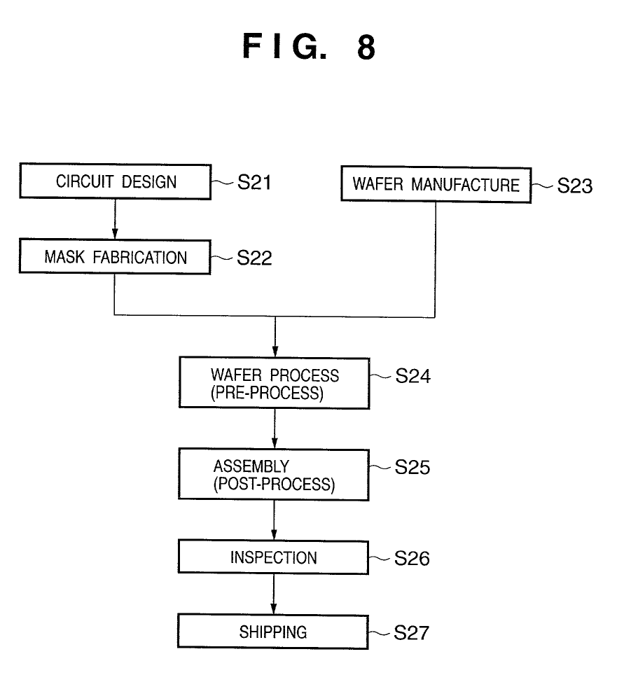

FIG. 8 illustrates the overall flow of a process for manufacturing semiconductor devices. The circuit for the device is designed at step 21 (circuit design). A mask on which the designed circuit pattern has been formed is fabricated at step 22 (mask fabrication).

Meanwhile, a wafer is manufactured using a material such as silicon or glass at step 23 (wafer manufacture).

The actual circuit is formed on the wafer by lithography, using the mask and wafer that have been prepared, at step 24 (wafer process), which is also referred to as “pre-treatment”. A semiconductor chip is obtained, using the wafer fabricated at step 24, at step 25 (assembly), which is also referred to as “post-treatment”. This step includes steps such as actual assembly (dicing and bonding) and packaging (chip encapsulation). The semiconductor device fabricated at step 25 is subjected to inspections such as an operation verification test and durability test at step 26 (inspection). The semiconductor device is completed through these steps and then is shipped (step 27).

The pre- and post-treatments are performed at separate special-purpose plants. Maintenance is carried out on a per-plant basis by the above-described remote maintenance system. Further, information for production management and equipment maintenance is communicated by data communication between the pre- and post-treatment plants via the Internet or leased-line network.

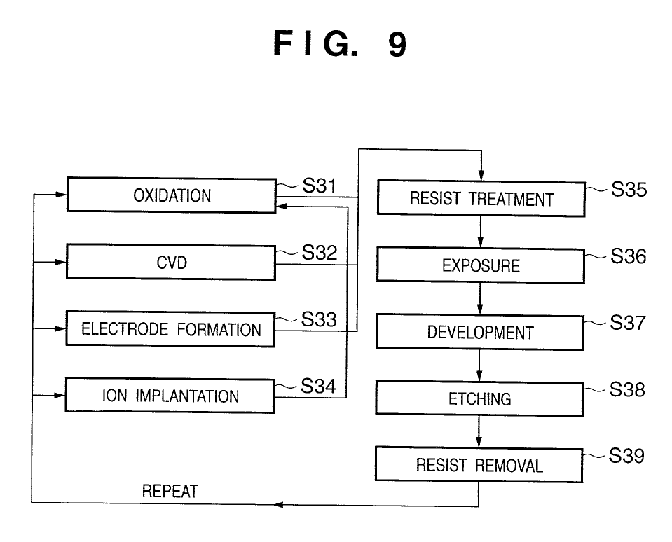

FIG. 9 is a flowchart illustrating the detailed flow of the wafer process mentioned above. The surface of the wafer is oxidized at step 31 (oxidation). An insulating film is formed on the wafer surface at step 32 (CVD), electrodes are formed on the wafer by vapor deposition at step 33 (electrode formation), and ions are implanted in the wafer at step 34 (ion implantation). The wafer is coated with a photoresist at step 35 (resist treatment), the wafer is exposed to the circuit pattern of the mask to print the pattern onto the wafer by the above-described exposure apparatus at step 36 (exposure), and the exposed wafer is developed at step 37 (development). Portions other than the developed photoresist are etched away at step 38 (etching), and unnecessary resist left after etching is performed is removed at step 39 (resist removal).

Multiple circuit patterns are formed on the wafer by implementing these steps repeatedly. Since the manufacturing equipment used at each step is maintained by the remote maintenance system described above, malfunctions can be prevented and quick recovery is possible if a malfunction should happen to occur. As a result, the productivity of semiconductor device manufacture can be improved over the prior art.

Thus, in accordance with the present invention as described above, a gas for raising oxygen concentration is blown in when maintenance is applied to an area in which oxygen concentration is set to a low value or to an area in which a toxic gas such as ozone, which is harmful to the human body, is produced. Furthermore, the oxygen concentration is sensed and maintenance is performed after the results of sensing indicate that a save level of oxygen concentration has been attained. This makes it possible to assure worker safety in the maintenance area and allows maintenance work to be performed safely at all times. In addition, maintenance can be performed in a shorter period of time and the efficiency of maintenance can be improved.

As many apparently widely different embodiments of the present invention can be made without departing from the spirit and scope thereof, it is to be understood that the invention is not limited to the specific embodiments thereof except as defined in the appended claims.

What is claimed is:

1. A semiconductor manufacturing apparatus comprising:
decision means for deciding start of a maintenance operation inside a chamber; and
supply means for supplying a prescribed area inside the chamber with a gas that contains oxygen if start of the maintenance operation has been decided by said decision means.

2. The apparatus according to claim 1, wherein the gas containing oxygen is clean, dry air.

3. The apparatus according to claim 1, further comprising an open/close sensor for sensing opening and closing of a panel provided in an outer wall of the chamber;
wherein said decision means decides start of the maintenance operation if said open/close sensor senses that the panel has been opened.

4. The apparatus according to claim 1, further comprising:
determination means for determining whether an environment in the prescribed area of the chamber has attained a safe level; and
notification means for giving notification of results of the determination based upon said results.

5. The apparatus according to claim 4, wherein said determination means includes a first sensor for sensing oxygen concentration, said first sensor being provided inside or in the vicinity of the prescribed area.

6. The apparatus according to claim 4, wherein said determination means includes a second sensor for sensing ozone concentration, said second sensor being provided inside or in the vicinity of the prescribed area.

7. The apparatus according to claim 4, further comprising a fan provided in the vicinity of the prescribed area for being driven at least for a period of time during which said determination means determines that the environment in the prescribed area is not at a safe level.

8. The apparatus according to claim 1, further comprising:
determination means for measuring concentration of a predetermined gas component in an environment in the prescribed area of the chamber, thereby determining whether the environment is at a safe level; and
a monitor for displaying results of measurement by said determination means.

9. The apparatus according to claim 1, wherein said decision means decides start of the maintenance operation inside the chamber if a command for transition to a maintenance mode has been entered via a control console.

10. The apparatus according to claim 1, further comprising:
determination means for determining whether an environment in the prescribed area of the chamber has attained a safe level; and
a lock mechanism for locking a cover, which is provided in an outer wall of the chamber, if said determination means determines that the environment is not at the safe level, and unlocking the cover if said determination means determines that the environment is at the safe level.

11. The apparatus according to claim 1, wherein a plurality of prescribed areas have been established inside the chamber, and said supply means has a gas supply unit for each of the plurality of prescribed areas.

12. The apparatus according to claim 11, wherein said decision means decides start of the maintenance operation for each of the plurality of prescribed areas.

13. The apparatus according to claim 12, wherein said supply means executes supply of the gas from whichever of the supply units corresponds to a prescribed area for which start of the maintenance operation has been decided by said decision means.

14. The apparatus according to claim 1, further comprising a display, a network interface and a computer for running network access software;
wherein maintenance information is communicated via a network.

15. The apparatus according to claim 14, wherein the network access software provides said display with a user interface for accessing a maintenance database provided by a vendor or user of the semiconductor manufacturing apparatus, thereby making it possible to obtain information from said database via the Internet or a leased-line network connected to said network.

16. A method of controlling a semiconductor manufacturing apparatus, comprising:
a decision step of deciding start of a maintenance operation inside a chamber; and
a supply step of supplying a prescribed area inside the chamber with a gas that contains oxygen if start of the maintenance operation has been decided by said decision step.

17. The method according to claim 16, wherein the gas containing oxygen is clean, dry air.

18. The method according to claim 16, wherein said decision step decides start of the maintenance operation if a panel, which is provided in an outer wall of the chamber, is sensed to have been opened by an open/close sensor for sensing opening and closing of the panel.

19. The method according to claim 16, further comprising:
a determination step of determining whether an environment in the prescribed area of the chamber has attained a safe level; and
a notification step of giving notification of results of the determination based upon said results.

20. The method according to claim 19, wherein said determination step determines whether the environment is at a safe level based upon results of sensing by a sensor for sensing oxygen concentration, said sensor being provided inside or in the vicinity of the prescribed area.

21. The method according to claim 19, wherein said determination step determines whether the environment is at a safe level based upon results of sensing by a sensor for sensing ozone concentration, said sensor being provided inside or in the vicinity of the prescribed area.

22. The method according to claim 19, further comprising a driving step of driving a fan provided in the vicinity of the prescribed area for at least for a period of time during which said determination step determines that the environment in the prescribed area is not at a safe level.

23. The method according to claim 1, further comprising:
a determination step of measuring concentration of a predetermined gas component in an environment in the prescribed area of the chamber, thereby determining whether the environment is at a safe level; and
a display step of displaying results of measurement on a monitor by said determination step.

24. The method according to claim 16, wherein said decision step decides start of the maintenance operation inside the chamber if a command for transition to a maintenance mode has been entered via a control console.

25. The method according to claim 16, further comprising:
a determination step of determining whether an environment in the prescribed area of the chamber has attained a safe level; and
a lock control step of locking a cover, which is provided in an outer wall of the chamber, if said determination step determines that the environment is not at the safe level, and unlocking the cover if said determination step determines that the environment is at the safe level.

26. The method according to claim 16, wherein a plurality of prescribed areas have been established inside the chamber, and said supply step supplies a gas from a supply unit provided for each of the plurality of prescribed areas.

27. The method according to claim 26, wherein said decision step decides start of the maintenance operation for each of the plurality of prescribed areas.

28. The apparatus according to claim 27, wherein said supply step executes supply of the gas from whichever of the supply units corresponds to a prescribed area for which start of the maintenance operation has been decided by said decision step.

29. A method of manufacturing devices, comprising steps of:
placing a plurality of semiconductor manufacturing apparatus in a plant; and
manufacturing a semiconductor device using said plurality of semiconductor manufacturing apparatus;
wherein at least one of said semiconductor manufacturing apparatus includes:
decision means for deciding start of a maintenance operation inside a chamber; and
supply means for supplying a prescribed area inside the chamber with a gas that contains oxygen if start of the maintenance operation has been decided by said decision means.

30. The method according to claim 29, further comprising the steps of:
connecting said plurality of semiconductor manufacturing apparatus by a local-area network;
connecting said local-area network and an external network outside the plant;
acquiring information concerning at least one of said semiconductor manufacturing apparatus from a database on the external network utilizing said local-area network and said external network; and
controlling said at least one semiconductor manufacturing apparatus based upon the information acquired.

31. The method according to claim 30, wherein maintenance information for said semiconductor manufacturing apparatus is obtained by accessing, by data communication via the external network, a database provided by a manufacturer of a semiconductor device or by a user of said manufacturing apparatus, or production management is performed by data communication with a semiconductor manufacturing plant other than the first mentioned semiconductor manufacturing plant via the external network.

32. A semiconductor manufacturing plant, comprising:
a plurality of items of semiconductor manufacturing apparatus;
a local-area network for interconnecting said plurality of semiconductor manufacturing apparatus; and
a gateway for connecting said local-area network and an external network outside said semiconductor manufacturing plant;
wherein at least one of said semiconductor manufacturing apparatus includes:
decision means for deciding start of a maintenance operation inside a chamber; and
supply means for supplying a prescribed area inside the chamber with a gas that contains oxygen if start of the maintenance operation has been decided by said decision means.

33. A method of maintaining a semiconductor manufacturing apparatus, comprising the steps of:
preparing a database, which stores information relating to maintenance of said semiconductor manufacturing apparatus, on an external network outside a plant at which said X-ray exposure apparatus has been installed;
connecting said X-ray exposure apparatus to a local-area network inside said plant; and
maintaining said X-ray exposure apparatus, based upon information that has been stored in said database, utilizing said external network and said local-area network;
wherein said semiconductor manufacturing apparatus includes:
decision means for deciding start of a maintenance operation inside a chamber; and
supply means for supplying a prescribed area inside the chamber with a gas that contains oxygen if start of the maintenance operation has been decided by said decision means.
